(19) United States
(12) Patent Application Publication
(10) Pub. No.: US 2007/0029576 A1
(43) Pub. Date: Feb. 8, 2007

(54) PROGRAMMABLE SEMICONDUCTOR DEVICE CONTAINING A VERTICALLY NOTCHED FUSIBLE LINK REGION AND METHODS OF MAKING AND USING SAME

(75) Inventors: Edward J. Nowak, Essex Junction, VT (US); Jed H. Rankin, South Burlington, VT (US); William R. Tonti, Essex Junction, VT (US)

Correspondence Address: SCULLY, SCOTT, MURPHY & PRESSNER, 400 GARDEN CITY PLAZA, GARDEN CITY, NY, 11530, US

(73) Assignee: INTERNATIONAL BUSINESS MACHINES CORPORATION, Armonk, NY (US)

(21) Appl. No.: 11/161,439

(22) Filed: Aug. 3, 2005

(51) Int. Cl. H01L 27/10

(52) U.S. Cl. 257/209

(57) ABSTRACT

The present invention relates to a programmable semiconductor device, preferably a FinFET or tri-gate structure, that contains a first contact element, a second contact element, and at least one fin-shaped fusible link region coupled between the first and second contact elements. The second contact element is laterally spaced apart from the first contact element, and the fin-shaped fusible link region has a vertically notched section. A programming current flowing through the fin-shaped fusible link region causes either significant resistance increase or formation of an electric discontinuity in the vertically notched section. Alternatively, the vertically notched section may contain a dielectric material, and application of a programming voltage between a gate electrode overlaying the vertically notched section and one of the contact elements breaks down the dielectric material and allows current flow between the gate electrode and the fin-shaped fusible link region.

### FIELD OF THE INVENTION

The present invention relates generally to programmable semiconductor devices that comprise electrical fuse and/or anti-fuse and methods of making and using such devices. More specifically, the present invention relates to electrical fuse and/or anti-fuse device structures that have a fin-shaped fusible link region with a vertical notch therein.

### BACKGROUND OF THE INVENTION

Fuses and anti-fuses are programmable electronic devices that are used in a variety of circuit applications. A fuse is normally closed or has a relatively lower resistance to allow electric current flowing therethrough, and when blown or programmed, it becomes open or has an increased resistance. An anti-fuse, on the other hand, is normally open or has relatively high resistance, and when an anti-fuse is blown or programmed, this results in a short circuit or a decreased resistance.

There are many applications for fuses and anti-fuses. One particular application is for customizing integrated circuits (IC's) after production. One IC configuration may be used for multiple applications by programming the fuses and/or anti-fuses (e.g., by blowing or rupturing selected fuses and anti-fuses) to deactivate and select circuit paths. Thus, a single integrated circuit design may be economically manufactured and adapted for a variety of custom uses. Fuses and anti-fuses may also be used to program chip identification (ID) after an integrated circuit is produced. A series of ones and zeros can be programmed in to identify the IC so that a user will know its programming and device characteristics. Further, fuses and anti-fuses can be used in memory devices to improve yields. Specifically, fuses or anti-fuses may be programmed to alter, disconnect or bypass defective cells or circuits and allow redundant memory cells to be used in place of cells that are no longer functional. Similarly, information may be rerouted using fuses and/or anti-fuses.

One type of fuse device is “programmed” or “blown” by using a laser to open a link after the semiconductor device is processed. This type of fuse device not only requires an extra processing step to program or “blow” the fuse devices where desired, but also requires precise alignment of the laser on the fuse device to avoid destroying neighboring devices. Additionally, due to laser size, depth penetration, and thermal considerations, these fuses must be placed in relative isolation, with no other active circuits adjacent, or in vertical proximity, thus a significant amount of real estate is consumed for each fuse.

Another type of fuse device is electrically programmable, which is usually referred to as an “e-fuse” or an “e-anti-fuse,” by using a programming current or voltage that is higher than the circuit's normal operating current or voltage to break down an insulator, or dielectric, thus to permanently change the electrical characteristics once the fuse is “blown” as compared to an unprogrammed fuse.

FIG. 1A shows the top view of a conventional design for an e-fuse device 1, which includes a first contact region 10A and a second contact region 10B that are electrically coupled together by a fuse region 12. Contacts 11 are formed in the contact regions 10A and 10B on the e-fuse 1. The fuse region 12 contains a center region 14 of a predetermined width, which is flanked by two notched regions 13 having widths that are significantly smaller than the predetermined width of the center region 14.

As shown in FIG. 1B, the e-fuse 1 contains a polysilicon layer 5 coated by a silicide layer 4 and is disposed on a semiconductor substrate 7. The semiconductor substrate 7 can be part of a larger integrated circuit device, and it may include various additional layers. An oxide layer 6 is formed between the e-fuse 1 and the substrate 7.

In an un-programmed state, electric current flows between the contact regions 10A and 10B through the silicide layer 4 of the fuse region 12. When a sufficiently large programming current is passed through the fuse region 12, the low-resistance silicide layer agglomerates and forms discontinuity between the contact regions 10A and 10B, as shown in FIG. 1C, thereby forcing electric current to flow through the underlying polysilicon layer 5 of higher sheet resistance instead. The resistance of the e-fuse 1 therefore increases significantly. Because the notched regions 13 have widths that are significantly smaller than that of the center region 14, silicide at the notched regions 13 agglomerates more easily than silicide in the center region 14, and formation of discontinuity due to programming can be readily localized in the notched regions 13 without affecting other regions of the e-fuse 1.

Another design of e-fuse includes a similar device structure as described hereinabove, except that a significantly larger programming current is employed, which not only causes agglomeration of the silicide material, but also causes the underlying polysilicon layer to separate. In this event, the fuse region 12 is completely opened and no longer allows flow of electric current therethrough.

A further design of e-fuse uses an intermediate programming current to cause agglomeration of the silicide material and to heat the underlying polysilicon layer, but without separating it. The joule heat generated by the programming current drives physical dopant atoms out of the underlying polysilicon layer, thereby increasing the resistance of the e-fuse to above that of a continuous silicide layer, but lower than that of an opened fuse.

Typical e-fuses require current flow and voltage levels at an appropriate level for a requisite time to program the fuse. In processes where the silicide is not titanium or cobalt silicide, which has a relatively low melting temperature (e.g., <1000° C.), but instead is a silicide of tungsten or another material that has a very high melting temperature (e.g., ≧3000° C.), much higher programming currents and longer response time are required in order to generate enough joule heat for melting the high temperature silicide material, which significantly increases the delay in response and the power consumption of the fuses not only for programming, but also for reading.

Therefore, there is a continuing need in the field to provide improved fuse or anti-fuse structures with reduced power consumption and response time.

### SUMMARY OF THE INVENTION

In one aspect, the present invention relates to a programmable semiconductor device that contains: (1) a first contact element, (2) a second contact element laterally spaced apart from the first contact element, and (3) at least one fin-shaped fusible link region coupled between the first and second contact elements, wherein the fin-shaped fusible link region comprises a vertically notched section.

The term “fin-shaped” as used herein refers to a three-dimensional (3D) structure having a first dimension that is significantly smaller than the other two dimensions. When such 3D structure is placed on a substrate surface, it is arranged so that the first dimension lies along a direction that is not perpendicular to, but is preferably parallel with, the substrate surface.

The term “vertically notched” as used herein refers to a structure in the fusible link region as described hereinabove, which is notched along a direction that is substantially perpendicular to a plane defined by upper surfaces of the first and second contact elements. A vertically notched structure is distinguished from a laterally or horizontally notched structure, which is notched along a direction that is substantially parallel to the plane defined by the upper surfaces of the first and second contact elements.

Another aspect of the present invention relates to a method of forming the above-described programmable semiconductor device, comprising:

(a) fabricating a first contact element, a second contact element laterally spaced apart from the first contact element, and at least one fin-shaped fusible link region coupled between the first and second contact elements; and

(b) forming a vertical notch at a first section of the at least one fin-shaped fusible link region.

Yet another aspect of the present invention relates to a method of programming the above-described programmable semiconductor device, by causing a predetermined programming current to flow through the fin-shaped fusible link region of the programmable semiconductor device for effectuating a resistance change in the vertically notched section of the fin-shaped fusible link region.

A further aspect of the present invention relates to a method of programming an electronic device. The electronic device specifically comprises a FinFET or tri-gate structure that includes: (i) a source region, (ii) a drain region laterally spaced apart from the source region, (iii) a channel region comprising a fin-shaped fusible link region, wherein the fin-shaped fusible link region comprises a vertically notched section consisting essentially of a dielectric oxide, and (iv) one or more gate electrodes positioned over the fin-shaped fusible link region for controlling electric current that flows through the fin-shaped fusible link region, wherein at least one gate electrode of the FinFET or tri-gate structure is positioned over the vertically notched section of the fin-shaped fusible link region. Such a method comprises applying a predetermined programming voltage between the at least one gate electrode and one of the source and drain regions to break down the dielectric oxide in the vertically notched section and to effectuate current flow between the at least one gate electrode and the fin-shaped fusible link region.

A still further aspect of the present invention relates to a programmable semiconductor device that comprises: (1) a first contact element, (2) a second contact element laterally spaced apart from the first contact element, and (3) at least one fusible link region coupled between the first and second contact elements, wherein the fusible link region comprises a vertically notched section.

Yet another aspect of the present invention relates to an electrically programmable semiconductor device, comprising a FinFET structure having a fin-shaped fusible link region with a vertically notched section.

Other aspects, features and advantages of the invention will be more fully apparent from the ensuing disclosure and appended claims.

### BRIEF DESCRIPTION OF THE DRAWINGS

FIGS. 1A-1C shows a conventional fuse structure with laterally notched regions.

FIG. 2 shows an elevated view of an exemplary fuse structure that has a fin-shaped fusible link region with a vertically notched section therein, according to one embodiment of the present invention.

FIGS. 3A-3B illustrates a method for programming the fuse shown in FIG. 2.

FIG. 4A shows an elevated view of an exemplary fuse structure that has a doped fin-shaped fusible link region with a vertically notched section therein, according to one embodiment of the present invention.

FIG. 4B illustrates a method for programming the fuse shown in FIG. 4A.

FIG. 5A shows an elevated view of an exemplary fuse structure that has a double-layer fin-shaped fusible link region with a vertically notched section therein, according to one embodiment of the present invention.

FIG. 5B illustrates a method for programming the fuse shown in FIG. 5A.

FIG. 6A shows an elevated view of an exemplary fuse structure that has a double-layer fin-shaped fusible link region with a vertically notched section that consists essentially of metal or silicide, according to one embodiment of the present invention.

FIG. 6B illustrates a method for programming the fuse shown in FIG. 6A.

FIG. 7A shows an elevated view of an exemplary anti-fuse structure that has a double layer fin-shaped fusible link region with a vertically notched section that consists essentially of a dielectric material, and a gate electrode overlaying the notched region of the anti-fuse, according to one embodiment of the present invention

FIG. 7B illustrates a method for programming the anti-fuse shown in FIG. 7A.

FIGS. 8A-14 illustrate the processing steps for forming a vertical notch in a fin-shaped semiconductor structure, according to one embodiment of the present invention.

### DETAILED DESCRIPTION OF THE INVENTION, AND PREFERRED EMBODIMENTS THEREOF

In the following description, numerous specific details are set forth, such as particular materials, dimensions, numbers of contacts, programming voltages and currents, in order to provide a thorough understanding of the invention. However, it will be appreciated by one of ordinary skill in the art that the invention may be practiced without these specific details. In other instances, well-known structures, and circuits have not been described in detail in order to avoid obscuring the invention.

It will be understood that when an element as a layer, region or substrate is referred to as being “on” another element, it can be directly one the other element or intervening elements may also be present. In contrast, when an element is referred to as being “directly on” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

It is also noted that the drawings of the present invention are provided for illustrative purposes and are not drawn to scale.

FIG. 2 shows an exemplary fuse device 20, according to one embodiment of the present invention. The fuse device 20 is disposed on a substrate 22 and contains a first contact element 24 having multiple contacts 23 on a surface thereof, and a second contact element 26 that is laterally spaced apart from the first contact element 24, while the second contact element 26 also has multiple contacts 25 on a surface thereof. The first and second contact elements 24 and 26 are coupled by a fin-shaped fusible link region 28, which contains a vertically notched section with a vertical notch 28a therein.

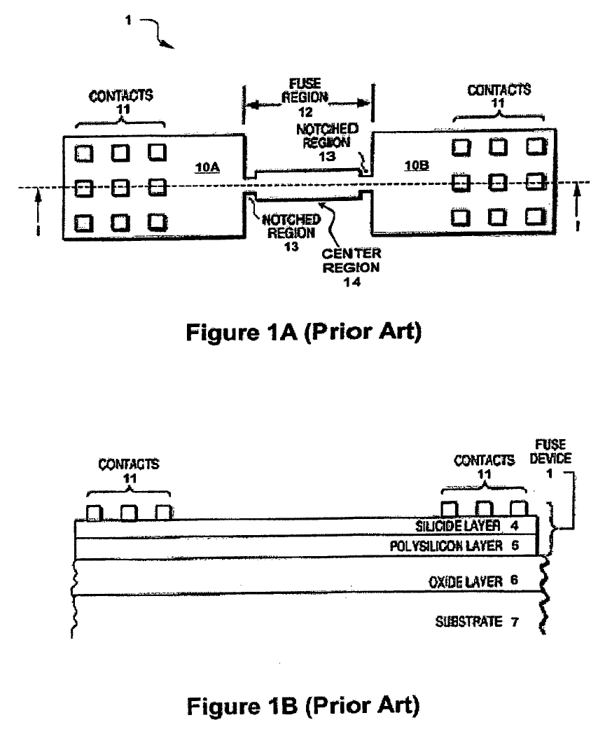

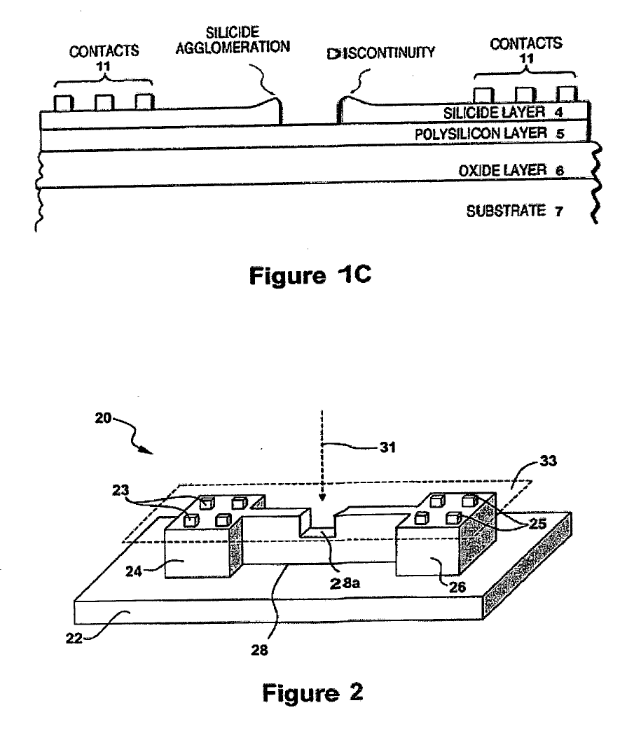

It is important to note that the fin-shaped fusible link region 28 of the fuse device 20 of the present invention is notched along a direction (see arrowhead 31 in FIG. 2) that is substantially perpendicular to a plane 33 (see the dotted lines in FIG. 2) defined by the upper surfaces of the first and second contact elements 24 and 26. In contrast, the conventional fuse 1 as shown in FIG. 1A contains a fuse region 31 that is notched at regions 13 along a “lateral” direction that is parallel to the plane defined by the upper surface of the first and second contact elements 10A and 10B. More importantly, the conventional fuse as shown in FIG. 1A is formed by lithographic techniques that require high precision and complex process control, while the fuse device of the present invention can be formed by non-lithographic techniques, which are much less complicated and less expensive in comparison with lithographic processes.

The fin-shaped fusible link region 28 may be formed by polysilicon, single crystal silicon, or any other suitable semiconductor materials, which include, but are not limited to, group IV semiconductors and groups III-V, II-VI, and IV-V compound semiconductors.

The substrate 22 may part of a larger integrated circuit device, and it may include a semiconductor susbstrate, diffusion regson, isolation regions, metal lines, dielectric layers, and various other components well known in the art and can be readily determined by a person ordinarily skilled in the art.

The contacts 23 as shown in FIG. 2 are substantailly squared in shape, but they may be rectangular, round, or have any other shape in alternative embodiments. Multiple contacts 23 operating in parallel may be used to ensure that the required programming current flows through the fuse device 20 without overheating the contacts 23. Preferably, the contacts 23 are coupled to metal interconnect lines (not shown) so that the fuse device 20 can be accessed for programming, sensing, or other uses. The contacts 23 can be formed of any conductive materials, and are preferably tungsten plugs.

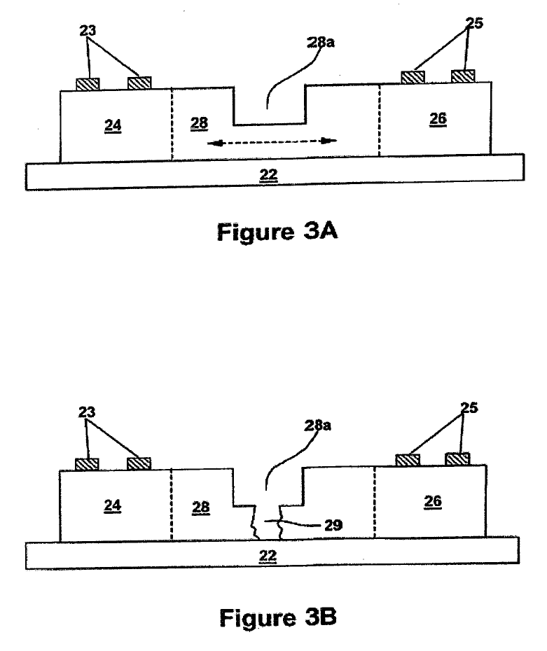

FIGS. 3A and 3B illustrates operation of the fuse device 20, according to one embodiment of the present invention. In an un-programmed state, electric current is passed between the first and second contact elements 24 and 26 through the fin-shaped fusible link region 28, as indicated by the arrowheads in FIG. 3A. During programming, a predetermined programming current that is higher than the current normally passed through the fusible link region 28 at the un-programmed state is provided to generate sufficient joule heat for melting the semiconductor material that forms the fusbile link region 28. The vertically notched section of the fusible link region 28 has a cross-sectional area that is sigificantly smaller than the cross-sectional area of other sections of the fusible link region 28, so semiconductor material in such a vertically notched section melts more easily than other sections, forming a discontinuity 29 thereat as shown in FIG. 3B. As a result, the fusible link region 28 is “open,” and the first and second contact elements 24 and 26 becomes electrically isolated from each other, as in a programmed state.

Alternatively, the fuse device of the present invention can be programmed by merely changing the resistance of the fin-shaped fusible link region, without forming a discontinuity or isolating the first and second contact elements.

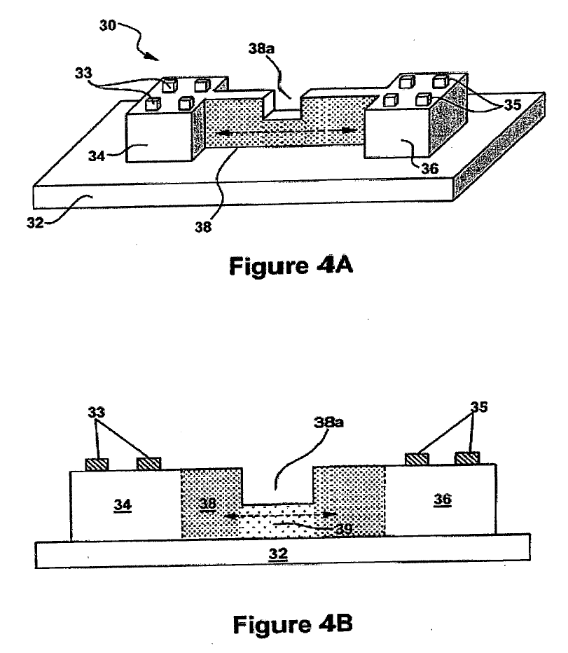

FIG. 4A shows another exemplary fuse device 30, according to one embodiment of the present invention. The fuse device 30 is disposed on a substrate 32 and contains a first contact element 34 having multiple contacts 33 on an upper surface thereof, and a second contact element 36 that is laterally spaced apart from the first contact element 34, while the second contact element 36 also has multiple contacts 35 on an upper surface thereof. The first and second contact elements 34 and 36 are coupled by a fin-shaped fusible link region 38, which contains a vertically notched section with a vertical notch 38a therein.

The fin-shaped fusible link region 38 is formed by a doped semiconductor material that comprises a dopant species, such as boron, phosphorus, antimony, gallium, arsenic, or other dopant species which changes the intrinsic electrical properties of the fuse material. The dopant species is susceptible to electromigration characteristics and is therefore employed in the present invention for adjusting the resistance of the fin-shaped fusible link region 38 in response to a programming current.

During operation, an electric current is passed between the first and second contact elements 34 and 36 through the fin-shaped fusible link region 38. The resistance of the fin-shaped fusible link region is determined by its dopant concentration. In an un-programmed state, the fin-shaped fusible link region has a first resistance. During programming, a predetermined programming current that is higher than the current normally passed through the fusible link region 38 at the un-programmed state is provided to generate joule heat in the fusbile link region 38. The vertically notched section of the fusible link region 38 has a cross-sectional area that is sigificantly smaller than the cross-sectional area of other sections of the fusible link region 38, so more jourle heat is generated in the vertically notched section of the fusible link region 38, which drives the dopant species out of the vertially notched section and results in a significantly lower dopant concentration at the vertially notched section 39, as shown in FIG. 4B. Although electric current can still flow between the first and second contact elements 34 and 36 through the fusible link region 38, the fusible link region 38 demonstrates a second resistance that is significantly different from the first resistance in the programmed state.

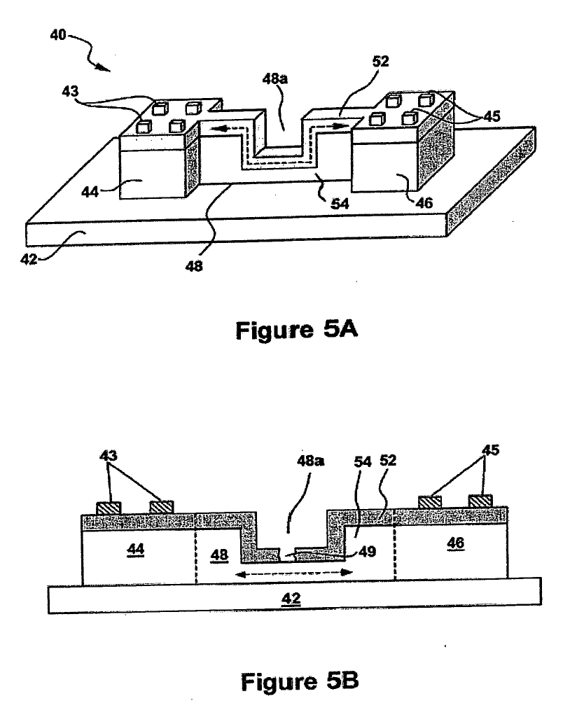

FIG. 5A shows another exemplary fuse device 40, according to one embodiment of the present invention. The fuse device 40 is disposed on a substrate 42 and contains a first contact element 44 having multiple contacts 43 on an upper surface thereof, and a second contact element 46 that is laterally spaced apart from the first contact element 44, while the second contact element 46 also has multiple contacts 45 on an upper surface thereof. The first and second contact elements 44 and 46 are coupled by a fin-shaped fusible link region 48, which contains a vertically notched section with a vertical notch 48a therein.

The fin-shaped fusible link region 48 contains a semiconductor material layer 54 and a metallic or silicide layer 52. The semiconductor material layer 54 may comprise polysilicon, single crystal silicon, or any other suitable semiconductor materials, which include, but are not limited to, group IV semiconductors and groups III-V, II-VI, and IV-V compound semiconductors. The sheet resistance of the semiconductor material layer 54 is within a range from about 200 ohm/sq to about 2000 ohm/sq, and more preferably from about 500 ohm/sq to about 1000 ohm/sq. The metallic or silicide layer 52 may comprise a metal (including metal alloy), such as titanium, tungsten, aluminum, and alloys there of, or a metal silicide (referred to hereinafter as “silicide”), such as nickel silicide, tungsten silicide, titanium silicide, cobalt silicide, and tantalum silicide, or any other silicide materials having electromigration characteristics. The sheet resistance of the metallic or silicide layer 52 is significantly lower than that of the semiconductor material layer 54, and typically ranges from about 1 ohm/sq to about 10 ohm/sq, and more preferably from about 3 ohm/sq to about 7 ohm/sq. Preferably, but not necessarily, the metallic or silicide layer 52 is characterized by a thickness that is significantly smaller than of the semiconductor material layer 54. For example, the semiconductor material layer 54 may have a thickness ranging from about 2000 Å to about 2500 Å, and the metallic or silicide layer 52 may have a thickness ranging from about 200 Å to about 250 Å.

In an un-programmed state, electric current is passed between the first and second contact elements 44 and 46 through the metallic or silicide layer 52 of a relatively lower resistance, as indicated by the arrowheads in FIG. 5A. During programming, a predetermined programming current that is higher than the current normally passed through the metallic or silicide layer 52 at the un-programmed state is provided, which causes agglomeration of the metallic or silicide and formation of a discontinuity 49 in the metallic or silicide layer 52 at the vertically notched section, as shown in FIG. 5B. Therefore, electrical current is forced to flow through the underlying semiconductor material layer 54 of a relatively higher resistance, as indicated by the arrowheads in FIG. 5B, and the fusible link region 48 demonstrates a programmed resistance that is significantly higher than the resistance in the un-programmed state.

Alternatively, the vertically notched region of the fusible link can contain a single layer of metal or silicide, so the formation of discontinuity therein in response to a programming current results in complete isolation of the first and second contact elements.

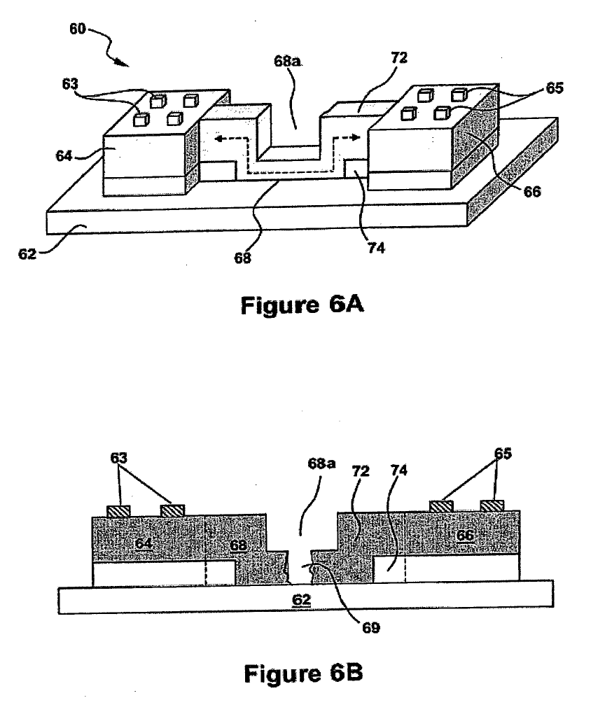

FIG. 6A shows an exemplary fuse device 60, as disposed on a substrate 62. The fuse device 60 contains a first contact element 64 having multiple contacts 63 on an upper surface thereof, and a second contact element 66 that is laterally spaced apart from the first contact element 64, while the second contact element 66 also has multiple contacts 65 on an upper surface thereof. The first and second contact elements 64 and 66 are coupled by a fin-shaped fusible link region 68, which contains a vertically notched section with a vertical notch 68a therein.

The fin-shaped fusible link region 68 of the fuse device 60 contains a semiconductor material layer 74 and a metallic or silicide layer 72, where the semiconductor layer 74 does not extend to the vertically notched region of the fin-shaped fusible link region 68. Consequently, the vertically notched region consists essentially of metal or silicide and is devoid of the semiconductor material. In such a manner, when a predetermined programming current is passed through the fin-shaped fusible link region 68, it causes agglomeration of the metal or silicide and formation of a discontinuity 69 in the metallic or silicide layer 72 at the vertically notched section of the fin-shaped fusible link region 68, which opens the fusible link region 68 and electrically isolates the first and second contact elements 64 and 66, as shown in FIG. 6B.

The electrically programmble devices of the present invention may be configured in a variety of ways. Preferably, it is configured a FinFET or tri-gate, which is a type of multi-gated metal-oxide-semiconductor field effect transistor (MOSFET) device wherein the gate structure wraps around a fin-shaped silicon body that forms the channel region of the FinFET or tri-gate. In the present invention, the first and second contact elements may form the source and drain regions of the FinFET or tri-gate; the fin-shaped fusible link region may form the fin-shaped channel region of the FinFET or tri-gate; and one or more gate electrodes, preferably polysilicon gates, are provided and positioned over the channel region for controlling the electrical current flowing through the fin-shaped channel region of the FinFET or tri-gate. In this manner, programming of the FinFET-based or tri-gate-based electrically programmable device is effected by adjusting the gate voltage.

In another embodiment of the presetn invention, the FinFET-based or tri-gate-based electrically programmable device constitutes an anti-fuse, wherein the vertically notched section of the fin-shaped fusible link region is formed of a dielectric material, including, but not limited to oxides, nitrides, oxynitrides, etc., which normally does not allow flow of electric current therethrough. When a sufficient high gate voltage is applied, the dielectric material of the vertically notched section can be broken down via high field injection, and form a low resistance path between the gate electrode and one of the first and second contact elements.

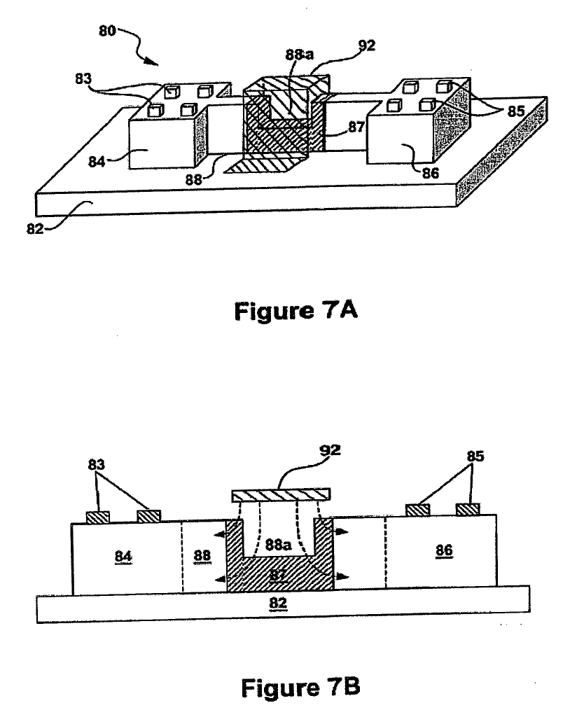

FIG. 7A shows an exemplary FinFET-based anti-fuse device 80, which is disposed on a substrate 82. The FinFET-based anti-fuse device 80 contains a source region (or a first contact element) 84 having multiple contacts 83 on an upper surface thereof, and a drain region (or a second contact element 86) that is laterally spaced apart from the source region 84, while the drain region 86 also has multiple contacts 85 on an upper surface thereof. The source and drain regions 84 and 86 are coupled by a fin-shaped channel region (or a fusible link region) 88, which contains a vertically notched section 87 with a vertical notch 88a therein. The vertically notched section 87 comprises a dielectric material and therefore electrically isolates the source and drain regions 84 and 86 under normal conditions.

A gate electrode 92 is provided, which wraps around the vertically notched section 87 of the fin-shaped channel region 88. A gate dielectric may be provided between the gate electrode 92 and the vertically notched section 87. Alternatively, the gate electrode 92 may directly contact the dielectric vertically notched section 87, which functions as the gate dielectric itself.

In an un-programmed state, no electric current is passed between the gate electrode 92 and the source and drain regions 84 and 86, due to the dielectric characteristics of the vertically notched section 87. During programming, a predetermined programming voltage is applied between the gate electrode 92 and one of the source and drain regions 84 and 86, which causes break-down of the dielectric material in the vertically notched section 87, thereby forming a low resistance current path between the gate electrode 92 and one of the source and drain regions 84 and 86, as indicated by the arrowheads in FIG. 7B.

Further, the present invention provides a method for forming the vertical notch in the fin-shaped fusible link region of the electrical programmable device of the present invention, which is described in greater details hereinafter.

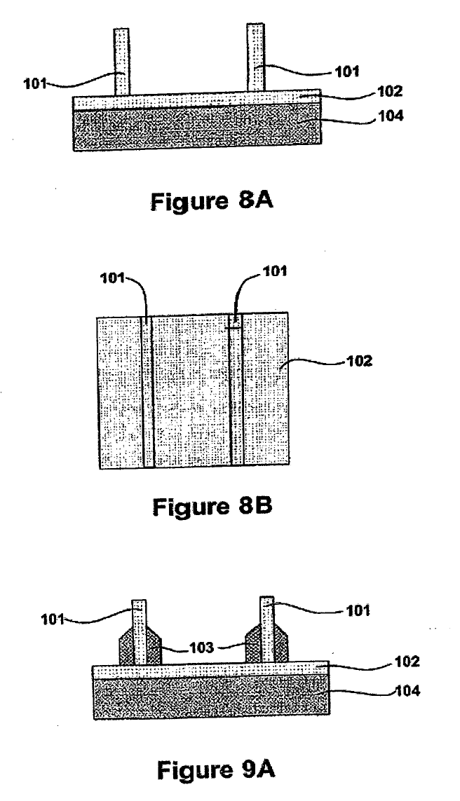

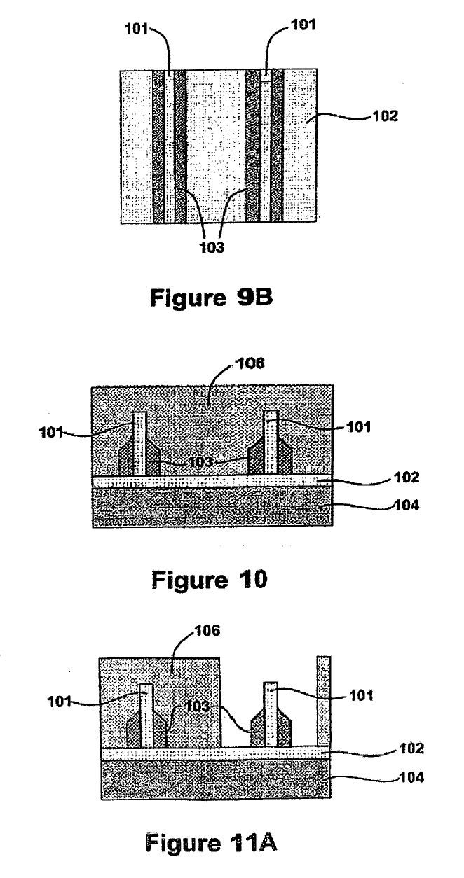

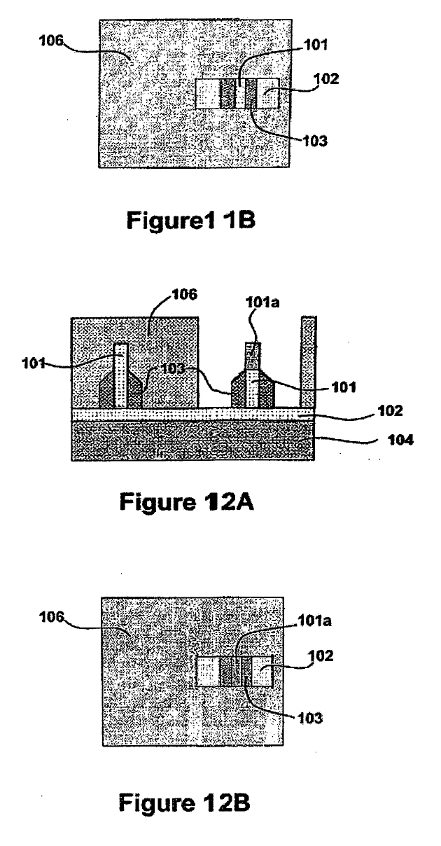

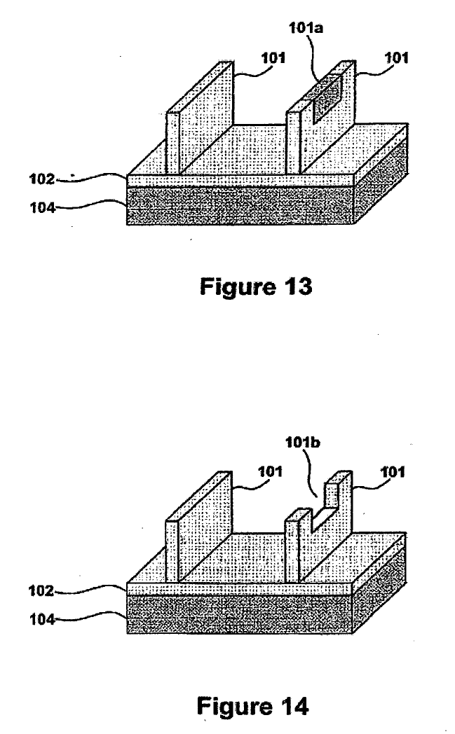

As shown in FIGS. 8A (cross-sectional view) and 8B (top view), two fin-shaped semiconductor structures 101 are provided, which are supported by a substrate structure that contains a semiconductor substrate 104 and an insulating layer 102, as shown in. One or more spacers 103 are formed on the side walls of the fin-shaped semiconductor structures 101, to protect a lower portion of the fin-shaped semiconductor structures 101 and to expose an upper portion thereof, as shown in FIGS. 9A (cross-sectional view) and 9B (top view). A thick dielectric layer 106 is then deposited over the fin-shaped semiconductor structures 101 and the spacers 103, as shown in FIG. 10, followed by selective etching of a predetermined region of the thick dielectric layer 106, to expose at least an unprotected portion of one fin-shaped semiconductor structure 101, as shown in FIGS. 11A (cross-sectional view) and 11B (top view). The exposed portion of the fin-shaped semiconductor structure 101 is subsequently subject to oxidation treatment and is converted into a dielectric oxide 101a, as shown in FIGS. 12A (cross-sectional view) and 12B (top view). The oxidation treatment can be done by exposing the material to oxygen at high temperatures. Alternatively, ion implantation of oxygen, germanium, or other ionic species can be done prior to oxidation to increase the local oxidation rate. After removing the thick dielectric layer 106 and the spacers 103, the two fin-shaped semiconductor structures 101 are again exposed, while one of which now contains a portion 101a that is formed of dielectric oxide, as shown in FIG. 13. By selectively etching the delectric oxide portion 101a, a vertical notch 101b is thus formed in the fin-shaped semiconductor structure 101, as shown in FIG. 14.

Additional processing steps can be employed for treating the vertically notched fin-shaped semiconductor structure, depending on the specific applications thereof. For example, for anti-fuse applications, the fin-shaped semiconductor structure can be further treated by selectively oxidizing the verticalled noticed section thereof.

The above-described method merely illustrates one method for forming the vertical notch in the fin-shaped fusible link region, while such vertical notch can be readily formed by various other methods known in the art.

Although the above description is provided primarily in terms of fuse and anti-fuse, for simplicity and illustration purposes only, the present invention is not thus limited, but is broadly applicable to other semiconductor device structures, with or without modifications and variations, as readily determinable by a person ordinarily skilled in the art according to the principles described herein.

While the invention has been described herein with reference to specific embodiments, features and aspects, it will be recognized that the invention is not thus limited, but rather extends in utility to other modifications, variations, applications, and embodiments, and accordingly all such other modifications, variations, applications, and embodiments are to be regarded as being within the spirit and scope of the invention.

What is claimed is:

1. A programmable semiconductor device, comprising: (1) a first contact element, (2) a second contact element laterally spaced apart from said first contact element, and (3) at least one fin-shaped fusible link region coupled between the first and second contact elements, wherein the fin-shaped fusible link region comprises a vertically notched section.

2. The programmable semiconductor device of claim 1, wherein the fin-shaped fusible link region comprises semiconductor material selected from the group consisting of polysilicon, single crystal silicon, group IV semiconductors, and groups III-V, II-VI, and IV-V compound semiconductors.

3. The programmable semiconductor device of claim 1, wherein the fin-shaped fusible link region comprises doped semiconductor material with a dopant selected from the group consisting of boron, phosphorus, antimony, gallium, and arsenic.

4. The programmable semiconductor device of claim 1, wherein the fin-shaped fusible link region comprises a semiconductor layer and a metallic or silicide layer formed directly on the semiconductor layer, the semiconductor layer having a first resistance, and the metallic or silicide layer having a second resistance lower than the first resistance.

5. The programmable semiconductor device of claim 4, wherein the semiconductor layer does not extend to the vertically notched section of the fin-shaped fuse region, and wherein said vertically notched section consists essentially of metal or silicide.

6. The programmable semiconductor device of claim 1, comprising a FinFET or tri-gate structure that includes: (i) a source region comprising the first contact element, (ii) a drain region comprising the second contact element, (iii) a channel region comprising the fin-shaped fusible link region, and (iv) one or more gate electrodes positioned over the fin-shaped fusible link region for controlling electric current that flows through said fin-shaped fusible link region.

7. The programmable semiconductor device of claim 6, wherein the vertically notched section of the fin-shaped fuse region consists essentially of a dielectric material, wherein at least one gate electrode of the FinFET or tri-gate structure is positioned over the vertically notched section of the fin-shaped fusible link region, wherein said FinFET or tri-gate structure further comprises a voltage applicator for applying a predetermined programming voltage between said at least one gate electrode and one of said first and second contact elements to break down the dielectric material in the vertically notched section and to effectuate current flow between the at least one gate electrode and the fin-shaped fusible link region.

8. A method of forming the programmable semiconductor device of claim 1, comprising:
(a) fabricating a first contact element, a second contact element laterally spaced apart from said first contact element, and at least one fin-shaped fusible link region coupled between the first and second contact elements; and
forming a vertical notch at a first section of said at least one fin-shaped fusible link region.

9. The method of claim 8, wherein the vertical notch is formed by steps comprising:
(a) selectively oxidizing at least a portion of the first section of said fin-shaped fusible link region along a vertical direction; and
(b) selectively etching the oxidized portion to form a vertical notch at the first section-.

10. The method of claim 8, further comprising the step of depositing a metallic or silicide layer over the first and second contact elements and the fin-shaped fusible link region.

11. The method of claim 8, further comprising the step of fabricating one or more gate electrodes over the fin-shaped fusible link region, thereby forming a FinFET or tri-gate structure that comprises: (i) a source region comprising the first contact element, (ii) a drain region comprising the second contact element, (iii) a channel region comprising the fin-shaped fusible link region, and (iv) the one or more gate electrodes for controlling electric current that flows through said fin-shaped fusible link region.

12. The method of claim 11, further comprising the step of oxidizing the first section of the fin-shaped fusible link region before fabrication of the gate electrodes to form a vertically notched section that consists essentially of a dielectric material, wherein at least one gate electrode of the FinFET or tri-gate structure is positioned over said vertically notched section, wherein a predetermined programming voltage is applied between said at least one gate electrode and one of said first and second contact elements to break down the dielectric material in the vertically notched section and to effectuate current flow between the at least one gate electrode and the fin-shaped fusible link region.

13. A method of programming the programmable semiconductor device of claim 1, comprising causing a predetermined programming current to flow through the fin-shaped fusible link region of said programmable semiconductor device for effectuating a resistance change in the vertically notched section of said fin-shaped fusible link region.

14. The method of claim 13, wherein the fin-shaped fusible link region comprises semiconductor material, and wherein the programming current melts the semiconductor material at the vertically notched section, thereby electrically isolating the first and second contact elements of the programmable semiconductor device.

15. The method of claim 13, wherein the fin-shaped fusible link region comprises doped semiconductor material with a dopant selected from the group consisting of boron, phosphorus, antimony, gallium, and arsenic, and wherein the programming current causes migration of the dopant out of the vertically notched section, thereby increasing the resistance of said vertically notched section.

16. The method of claim 13, wherein the fin-shaped fusible link region comprises a semiconductor layer having a metallic or silicide layer formed directly thereon, the semiconductor layer having a first resistance, and the metallic or silicide layer having a second resistance lower than the first resistance, and wherein the programming current that flows through the fin-shaped fusible link region causes agglomeration of metal or silicide and formation of discontinuity in the metallic or silicide layer at the vertically notched section, thereby resulting in resistance change in the vertically notched section.

17. The method of claim 16, wherein the semiconductor layer does not extend to the vertically notched section of the fin-shaped fuse region, wherein said vertically notched section consists essentially of metal or silicide, so that formation of discontinuity in the metallic or silicide layer at the vertically notched section electrically isolates the first contact element from the second contact element.

18. A method of programming an electronic device, wherein said electronic device comprises a FinFET or tri-gate structure that includes: (i) a source region, (ii) a drain region laterally spaced apart from said source region, (iii) a channel region comprising a fin-shaped fusible link region, wherein said fin-shaped fusible link region comprises a vertically notched section consisting essentially of a dielectric material, and (iv) one or more gate electrodes positioned over the fin-shaped fusible link region for controlling electric current that flows through said fin-shaped fusible link region, wherein at least one gate electrode of the FinFET or tri-gate structure is positioned over the vertically notched section of the fin-shaped fusible link region, said method comprising applying a predetermined programming voltage between said at least one gate electrode and one of said source and drain regions to break down the dielectric material in the vertically notched section and to effectuate current flow between the at least one gate electrode and the fin-shaped fusible link region.

19. A programmable semiconductor device, comprising: (1) a first contact element, (2) a second contact element laterally spaced apart from said first contact element, and (3) at least one fusible link region coupled between the first and second contact elements, wherein the fusible link region comprises a vertically notched section.

20. An electrically programmable semiconductor device, comprising a FinFET or tri-gate structure having a fin-shaped fusible link region with a notched section.
